(19) United States
(12) Patent Application Publication
(10) Pub. No.: US 2025/0390653 A1
(43) Pub. Date: Dec. 25, 2025

(54) ECO METHOD BASED ON ADAPTIVE LEARNING

(71) Applicant: Easy-Logic Technology (Shenzhen) Co., Ltd., Shenzhen (CN)

(72) Inventors: Xiao ZHANG, Shenzhen (CN); Yi DIAO, Shenzhen (CN); Xing WEI, Shenzhen (CN); Feng YUAN, Shenzhen (CN); Xiaoqing YANG, Shenzhen (CN); Linhan ZHENG, Shenzhen (CN); Lin DING, Shenzhen (CN)

(21) Appl. No.: 18/780,410

(22) Filed: Jul. 22, 2024

(30) Foreign Application Priority Data
Jun. 19, 2024 (CN) 202410797610.2

(51) Int. Cl. G06F 30/327

(52) U.S. Cl. CPC G06F 30/327

(57) ABSTRACT

The present invention provides an ECO method based on adaptive learning applied to ECO operations of netlists in different stages in a chip design process. The method comprises acquiring a first netlist subjected to an ECO in a previous stage and a second netlist to be subjected to an ECO in a current stage; determining a position where the ECO of the previous stage involves netlist modification based on a structural similarity between the first netlist and the second netlist, and delineating an input boundary and an output boundary in the first netlist; searching for, in the second netlist, matching signals matching the input boundary and output boundary delineated in the first netlist; delineating a boundary range of the second netlist to be subjected to the ECO based on the matching signals; and performing the ECO in the delineated boundary range. The method improves efficiency and accuracy of the ECO.

### CROSS-REFERENCE TO RELATED APPLICATIONS

The present application claims priority to Chinese Patent Application No. 2024107976102, filed Jun. 19, 2024, the entire disclosure of which is incorporated herein by reference.

### TECHNICAL FIELD

The present invention relates to the technical field of ECOs, and in particular, to an ECO method based on adaptive learning.

### BACKGROUND ART

An engineering change order (ECO) refers to a process of directly modifying an integrated circuit in a digital chip design process, that is, a process of modifying a gate-level netlist of any design stage (a synthesis stage, a DFT stage, a PNR stage, and the like) to make a modified circuit logic function consistent with a new expectation.

When designing a chip, a chip designer usually writes RTL first performs logic synthesis on the RTL to obtain a synthesis netlist, then adds DFT settings such as scan chain to obtain a DFT netlist, and then performs placement and routing to obtain a PNR netlist. These netlists in different stages often have very strong similarities. A conventional ECO method is to perform an ECO on a netlist in any stage, so that the netlist is equivalent to new RTL logic after the change. However, this conventional method does not take into account a similarity between netlists of adjacent stages at all, such as a similarity between the DFT netlist and the synthesis netlist, so that a result of the ECO is poor in some cases, such as a situation in which many hierarchical structures in a netlist in a stage are flattened.

ECO methods in the prior art often lack self-adaptability, and an ECO generally involves modification of netlists in a plurality of stages. The conventional ECO method usually only pays attention to modification of a netlist in a current stage, ignoring a correlation and impact with netlists in other stages. This may result in that an ECO of a netlist in a subsequent stage is regarded as a completely independent ECO task, and it is impossible to refer to a completed ECO of a previous stage to improve quality and save time, thus increasing a design cost and risk. With the increase of a chip design complexity, the number of logic modules and circuit units in a netlist increases sharply, which makes the ECO process more complicated and tedious. The conventional ECO method is often inefficient and prone to errors when dealing with a large number of modifications.

### SUMMARY OF THE INVENTION

The present invention provides an ECO method based on adaptive learning, which is used in an ECO of a netlist in any stage in chip design, aiming to quickly implement the ECO of the netlist in the current stage based on an ECO solution of the netlist in the previous stage by using a similarity between netlists of adjacent stages.

The solution of the present invention is as follows.

In a first aspect, the present invention provides an ECO method based on adaptive learning. The method comprises the following steps.
Step S1: acquiring a first netlist subjected to an ECO in a previous stage and a second netlist to be subjected to an ECO in a current stage:

The stages comprise a synthesis stage, a DFT stage, and a PNR stage in the order from front to back, and corresponding stage netlists are: a synthesis netlist, a DFT netlist, and a PNR netlist.
Step S2: determining a position where the ECO of the previous stage involves netlist modification based on a structural similarity between the first netlist and the second netlist, and delineating an input boundary and an output boundary in the first netlist.

Further, the determining a position where the ECO of the previous stage involves netlist modification based on a structural similarity between the first netlist and the second netlist in step S2 comprises the following steps:
S21: performing a difference comparison between the first netlist and the second netlist to identify a structural difference therebetween;
S22: locating, based on the structural difference, a logic module or circuit unit specifically modified by the ECO of the previous stage; and
S23: analyzing the modified logic module or circuit unit to determine an input signal and output signal corresponding thereto.

The input boundary and the output boundary completely contain the logic module or circuit unit modified by the ECO of the previous stage and a circuit element directly related thereto.

The delineating an input boundary and an output boundary in the first netlist in step S2 comprises the following steps:
S24: identifying, from the first netlist based on the input signal and output signal determined in step S23, circuit elements directly connected to these signals;
S25: connecting circuit elements directly connected to the input signal and an upstream part to form the input boundary; and
S26: connecting circuit elements directly connected to the output signal and a downstream part to form the output boundary.
Step S3: searching for, in the second netlist, matching signals matching the input boundary and output boundary delineated in the first netlist.

In step S3, during searching for the matching signals matching the input boundary and the output boundary delineated in the first netlist, if direct matching fails, a search range in the second netlist is gradually expanded until the signals matching the input boundary and the output boundary in the first netlist are found.

For the input boundary, if the matching signals are in a main input PI direction, the search range is expanded in a PI direction; or

for the output boundary, if the matching signals are in a main output PO direction, the search range is expanded in a PO direction.
Step S4: delineating a boundary range of the second netlist to be subjected to the ECO based on the matching signals.

If the ECO of the previous stage involves modification of a plurality of logic modules or circuit units, when the position where the ECO of the previous stage involves netlist modification, all modified logic modules or circuit units are identified, and for each modified logic module or circuit unit, step S23 is performed to determine an input signal and output signal corresponding thereto; and

based on the input signals and the output signals of all the modified logic modules or circuit units, an input boundary and an output boundary are comprehensively delineated in the first netlist.
Step S5: performing the ECO in the boundary range of the second netlist to be subjected to the ECO.

No ECO is performed outside the boundary range of the second netlist to be subjected to the ECO.

The method further comprises a verification step for verifying functional correctness of the second netlist after the ECO, and the verification step comprises:

using a logic equivalence check tool perform function logic equivalence check on the second netlist after the ECO to confirm that a function of the second netlist is logically equivalent to the function of the first netlist.

In a second aspect, the present invention provides an electronic design automation system. The system comprises: a memory configured to store netlists in different stages; and a processor configured to perform the ECO method based on adaptive learning according to the first aspect.

In a third aspect, the present invention provides a computer-readable storage medium comprising instructions, wherein when the instructions are executed by a computer, the computer is enabled to perform the ECO method based on adaptive learning according to the first aspect.

Compared with the prior art, the present invention has the following beneficial effects.

The present invention solves the problem that a conventional ECO algorithm cannot achieve a good result in some specific situations, including but not limited to a situation where a hierarchical structure of a chip netlist is severely ungrouped or even all flattened. A conventional fully-automatic ECO algorithm needs to add a lot of new instances, but a backend team may not be able to accept such a large ECO change. According to the solution provided in the present invention, a similarity between netlists of adjacent stages can be used to learn a change in ECOs of adjacent stages by means of an algorithm, thereby obtaining a good ECO result and greatly saving the ECO time.

### BRIEF DESCRIPTION OF THE DRAWINGS

FIG. 1 is a flowchart of an ECO method based on adaptive learning according to the present invention.

### DETAILED DESCRIPTION OF EMBODIMENTS

To make the objectives, technical solutions and advantages of the present invention clearer, the following clearly and completely describes the technical solutions in the present invention. Apparently, the described embodiments are some but not all of the embodiments of the present invention. All other embodiments obtained by those of ordinary skill in the art based on the embodiments of the present invention without creative efforts shall fall within the protection scope of the present invention.

### Embodiment 1

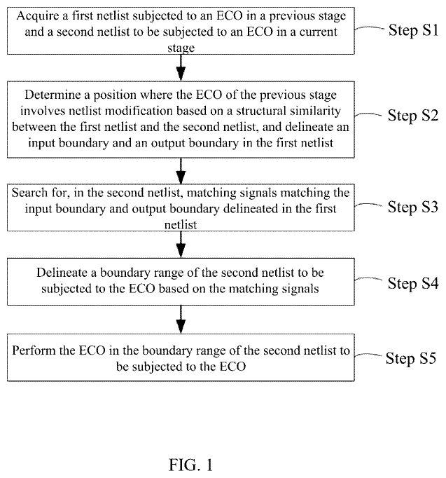

FIG. 1 is a flowchart of an ECO method based on adaptive learning according to this embodiment. The method includes the following steps.
Step S1: Acquire a first netlist subjected to an ECO in a previous stage and a second netlist to be subjected to an ECO in a current stage.

The stages comprise a synthesis stage, a DFT stage, and a PNR stage in the order from front to back, and corresponding stage netlists are: a synthesis netlist, a DFT netlist, and a PNR netlist.

It should be noted that normally, designing a chip needs a plurality of steps: RTL->synthesis netlist->DFT netlist->PNR netlist, which are all in the same design drawing, but are only different stages. However, the conventional flow does not consider a structural similarity between netlists of different stages, which wastes this information. In the learning ECO method based on adaptive learning according to this embodiment, the structural similarity between netlists of different stages is used to perform some training, thus narrowing the scope of the solution.

For example, when an all flattened netlist is modified in any small place, if a tool cannot quickly locate this small place of modification, the tool has to search for this place of modification in a large range of the whole netlist. However, if a structural similarity is used to obtain the range of ECO modification on the DFT netlist without modification elsewhere, the DFT netlist may be compared with the PNR netlist step by step by using the structural similarity, and for every signal on DFT, a corresponding signal is found on the PNR netlist.
Step S2: Determine a position where the ECO of the previous stage involves netlist modification based on a structural similarity between the first netlist and the second netlist, and delineate an input boundary and an output boundary in the first netlist.

The determining a position where the ECO of the previous stage involves netlist modification based on a structural similarity between the first netlist and the second netlist in step S2 comprises the following steps.
S21: Perform a difference comparison between the first netlist and the second netlist to identify a structural difference therebetween.

Signals matching the input boundary and the output boundary can be matched based on the similarity by engineering experience or direct diff, which is not specifically limited in this embodiment.
S22: Locate, based on the structural difference, a logic module or circuit unit specifically modified by the ECO of the previous stage.
S23: Analyze the modified logic module or circuit unit to determine an input signal and output signal corresponding thereto.

The input boundary and the output boundary completely contain the logic module or circuit unit modified by the ECO of the previous stage and a circuit element directly related thereto.

With regard to a simple method for determining a position where the ECO of the previous stage involves netlist modification, for example, a module includes a submodule A and a submodule B, and if the submodule B is subjected to the ECO in ECO modification in the previous stage, at this stage, only operation within the scope of the submodule B needs to be considered without considering anything other than the submodule A and the module.

However, for complex situations, for example, designers remove a hierarchical structure in pursuit of an optimization effect, such as removing the submodule B and ungrouping the submodule into an upper module (this operation is referred to as ungroup). In this case, the submodule B loses a clear boundary, and the whole module needs to be considered during the ECO. In extreme cases, all hierarchical structures are all flattened, which is referred to as flatten all. In this case, for any ECO, an algorithm operation is matched globally (the whole chip).

In the above process, the “Learning ECO” mentioned is essentially a heuristic method based on historical data or netlist information of adjacent stages, which is used to predict and expand a signal boundary. This method can significantly reduce a solution space that ECO algorithm needs to search for, and especially during dealing with large-scale complex designs or operations such as ungroup and flatten, performance of conventional algorithms may drop sharply. By using the similarity between netlists, the Learning algorithm can guide the ECO algorithm to find an optimal solution more efficiently, thus improving efficiency and quality of the whole design process. The delineating an input boundary and an output boundary in the first netlist in step S2 comprises the following steps.
S24: Identify, from the first netlist based on the input signal and output signal determined in step S23, circuit elements directly connected to these signals.
S25: Connect circuit elements directly connected to the input signal and an upstream part to form the input boundary.
S26: Connect circuit elements directly connected to the output signal and a downstream part to form the output boundary.
Step S3: Search for, in the second netlist, matching signals matching the input boundary and output boundary delineated in the first netlist.

In step S3, during searching for the matching signals matching the input boundary and the output boundary delineated in the first netlist, if direct matching fails, a search range in the second netlist is gradually expanded until the signals matching the input boundary and the output boundary in the first netlist are found.

For the input boundary, if the matching signals are in a main input PI direction, the search range is expanded in a PI direction; or

for the output boundary, if the matching signals are in a main output PO direction, the search range is expanded in a PO direction.

It should be noted that the input boundary is upstream (where the signal comes from) of an ECO point, and the output boundary is downstream of the ECO point (to which the signal passes through the ECO point). These two boundaries are delineated, and the ECO point is between these two boundaries, so that the boundary range to be subjected the ECO is determined.
Step S4: Delineate a boundary range of the second netlist to be subjected to the ECO based on the matching signals.

If the ECO of the previous stage involves modification of a plurality of logic modules or circuit units, when the position where the ECO of the previous stage involves netlist modification, all modified logic modules or circuit units are identified, and for each modified logic module or circuit unit, step S23 is performed to determine an input signal and output signal corresponding thereto; and

based on the input signals and the output signals of all the modified logic modules or circuit units, an input boundary and an output boundary are comprehensively delineated in the first netlist.
Step S5: Perform the ECO in the boundary range of the second netlist to be subjected to the ECO.

No ECO is performed outside the boundary range of the second netlist to be subjected to the ECO.

The method further comprises a verification step for verifying functional correctness of the second netlist after the ECO, and the verification step comprises:
using a logic equivalence check tool perform function logic equivalence check on the second netlist after the ECO to confirm that a function of the second netlist is logically equivalent to the function of the first netlist.

### Embodiment 2

This embodiment provides an electronic design automation system. The system comprises: a memory configured to store netlists in different stages; and a processor configured to perform the ECO method based on adaptive learning according to Embodiment 1.

The memory comprises a flash memory, a hard disk, a multimedia card, a card memory (such as an SD or DX memory), a random access memory (RAM), a static random access memory (SRAM), a read-only memory (ROM), an electrically erasable programmable read-only memory (EEPROM), a programmable read-only memory (PROM), a magnetic memory, a magnetic disk, an optical disc, and the like. The memory may be an internal storage unit of a computer device, such as a hard disk or an internal memory of the computer device, or an external storage of the computer device, such as a plug-in hard disk provided on the computer device, a smart media card (SMC), a secure digital (SD) card, and a flash Card.

### Embodiment 3

This embodiment provides a computer-readable storage medium comprising instructions. When the instructions are executed by a computer, the computer is enabled to perform the ECO method based on adaptive learning according to Embodiment 1.

The present invention has been illustrated by specific embodiments, and those skilled in the art should understand that various changes and equivalent substitutions can be further made to the present invention without departing from the scope of the present invention. In addition, various modifications can be made to the present invention for specific situations or materials without departing from the scope of the present invention. Therefore, the present invention is not limited to the specific embodiments disclosed, but should include all implementations falling within the scope of the claims of the present invention.

What is claimed is:

1. An ECO method based on adaptive learning, characterized in that the method is used in an ECO of a netlist in any stage of a chip design, and the method comprises the following steps:
step S1: acquiring a first netlist subjected to the ECO in a previous stage and a second netlist to be subjected to the ECO in a current stage;
step S2: determining a position where the ECO of the previous stage involves netlist modification based on a structural similarity between the first netlist and the second netlist, and delineating an input boundary and an output boundary in the first netlist;
step S3: searching for, in the second netlist, matching signals matching the input boundary and output boundary delineated in the first netlist;
step S4: delineating a boundary range of the second netlist to be subjected to the ECO based on the matching signals; and
step S5: performing the ECO in the boundary range of the second netlist to be subjected to the ECO.

2. The ECO method based on adaptive learning according to claim 1, characterized in that the stages comprise at least a synthesis stage, a DFT stage, and a PNR stage in the order from front to back, and corresponding stage netlists are: a synthesis netlist, a DFT netlist, and a PNR netlist.

3. The ECO method based on adaptive learning according to claim 1, characterized in that no ECO is performed outside the boundary range of the second netlist to be subjected to the ECO.

4. The ECO method based on adaptive learning according to claim 1, characterized in that the determining a position where the ECO of the previous stage involves netlist modification based on a structural similarity between the first netlist and the second netlist in step S2 comprises the following steps:
S21: performing a difference comparison between the first netlist and the second netlist to identify a structural difference therebetween;
S22: locating, based on the structural difference, a logic module or circuit unit specifically modified by the ECO of the previous stage; and
S23: analyzing the modified logic module or circuit unit to determine an input signal and output signal corresponding thereto.

5. The ECO method based on adaptive learning according to claim 4, characterized in that the input boundary and the output boundary completely comprise the logic module or circuit unit modified by the ECO of the previous stage and a circuit element directly related thereto; and the delineating an input boundary and an output boundary in the first netlist in step S2 comprises the following steps:
S24: identifying, from the first netlist based on the input signal and output signal determined in step S23, circuit elements directly connected to these signals;
S25: connecting circuit elements directly connected to the input signal and an upstream part to form the input boundary; and
S26: connecting circuit elements directly connected to the output signal and a downstream part to form the output boundary.

6. The ECO method based on adaptive learning according to claim 5, characterized in that in step S3, during searching for the matching signals matching the input boundary and the output boundary delineated in the first netlist, if direct matching fails, a search range in the second netlist is gradually expanded until the signals matching the input boundary and the output boundary in the first netlist are found; and
for the input boundary, if the matching signals are in a main input PI direction, the search range is expanded in a PI direction; or
for the output boundary, if the matching signals are in a main output PO direction, the search range is expanded in a PO direction.

7. The ECO method based on adaptive learning according to claim 4, characterized in that if the ECO of the previous stage involves modification of a plurality of logic modules or circuit units, when the position where the ECO of the previous stage involves netlist modification, all modified logic modules or circuit units are identified, and for each modified logic module or circuit unit, step S23 is performed to determine an input signal and output signal corresponding thereto; and
based on the input signals and the output signals of all the modified logic modules or circuit units, an input boundary and an output boundary are comprehensively delineated in the first netlist.

8. The ECO method based on adaptive learning according to claim 1, characterized in that further comprising a verification step for verifying functional correctness of the second netlist after the ECO, wherein the verification step comprises:
using a formal verification tool to perform function logic equivalence check on the second netlist after the ECO to confirm that a function of the second netlist is consistent with an expectation before the ECO.

9. An electronic design automation system, characterized in that comprising: a memory configured to store netlists in different stages; and a processor configured to perform the ECO method based on adaptive learning according to claim 1.

10. A computer-readable storage medium comprising instructions, wherein when the instructions are executed by a computer, the computer is enabled to perform the ECO method based on adaptive learning according to claim 1.
